(19) United States
(12) Patent Application Publication
(10) Pub. No.: US 2024/0249956 A1
(43) Pub. Date: Jul. 25, 2024

(54) SUBSTRATE PROCESSING APPARATUS

(71) Applicant: Tokyo Electron Limited, Tokyo (JP)

(72) Inventors: Yohei NAKAGOMI, Nirasaki City, Yamanashi (JP); Ryo KUWAJIMA, Nirasaki City, Yamanashi (JP); Yohei MIDORIKAWA, Nirasaki City, Yamanashi (JP)

(21) Appl. No.: 18/566,183

(22) PCT Filed: May 26, 2022
(86) PCT No.: PCT/JP2022/021525

§ 371 Date: Dec. 1, 2023

(30) Foreign Application Priority Data
Jun. 4, 2021 (JP) 2021-094404
Jun. 30, 2021 (JP) 2021-109375

(51) Int. Cl. H01L 21/67

(52) U.S. Cl. CPC H01L 21/67017

(57) ABSTRACT

A substrate processing apparatus for processing a substrate, includes: an inner chamber in which the substrate is accommodated; an outer chamber provided outside the inner chamber, and a processing gas supplier configured to supply a processing gas to an interior of the inner chamber, wherein the inner chamber is configured to be detachable from the outer chamber, and the outer chamber is provided such that the outer chamber does not come into contact with the processing gas supplied to the interior of the inner chamber.

### TECHNICAL FIELD

The present disclosure relates to a substrate processing apparatus.

### BACKGROUND

Patent Document 1 discloses a substrate processing apparatus which processes a substrate accommodated in a chamber. The chamber is usually made of aluminum (Al). An inner surface of the chamber is subjected to surface oxidation treatment. In a case where a hydrogen fluoride gas is supplied into the chamber, a portion or the entirety of the inner surface of the chamber is formed of Al or an Al alloy that has not been subjected to the surface oxidation treatment.

### PRIOR ART DOCUMENT

### Patent Document

Patent Document 1: Japanese Laid-Open Patent Publication No. International Publication No. WO2007/072708

A technique according to the present disclosure provides a substrate processing apparatus which is configured to be adapted for various processing gases when processing a substrate with a processing gas.

### SUMMARY

An aspect of the present disclosure provides a substrate processing apparatus for processing a substrate, which includes: an inner chamber in which the substrate is accommodated; an outer chamber provided outside the inner chamber; and a processing gas supplier configured to supply a processing gas to an interior of the inner chamber, wherein the inner chamber is configured to be detachable from the outer chamber, and the outer chamber is provided such that the outer chamber does not come into contact with the processing gas supplied to the interior of the inner chamber.

According to the present disclosure, it is possible to provide a substrate processing apparatus which is configured to be adapted for various processing gases when processing a substrate with a processing gas.

### BRIEF DESCRIPTION OF DRAWINGS

FIG. 1 is a vertical cross-sectional view schematically illustrating a configuration of a wafer processing apparatus according to a first embodiment.

FIG. 2 is a vertical cross-sectional view schematically illustrating the configuration of the wafer processing apparatus according to the first embodiment.

FIG. 3 is an explanatory view illustrating a gas system in the wafer processing apparatus according to the first embodiment.

FIG. 4 is a vertical cross-sectional view schematically illustrating configurations of a chamber and the vicinity of the chamber according to the first embodiment.

FIG. 5 is a perspective view schematically illustrating the configuration of the chamber according to the first embodiment.

FIG. 6 is a perspective view schematically illustrating the configuration of the chamber according to the first embodiment.

FIG. 7 is a perspective view schematically illustrating a configuration of an inner chamber according to the first embodiment.

FIG. 8 is a plan view schematically illustrating the configuration of the inner chamber according to the first embodiment.

FIG. 9 is a perspective view schematically illustrating a configuration of an outer chamber according to the first embodiment.

FIG. 10 is a plan view schematically illustrating the configuration of the outer chamber according to the first embodiment.

FIG. 11 is an explanatory view illustrating a seal structure of a hermetically closed space in a loading/unloading port of the inner chamber according to the first embodiment.

FIG. 12 is an explanatory view illustrating the seal structure of the hermetically closed space in the loading/unloading port of the inner chamber according to the first embodiment.

FIG. 13 is an explanatory view illustrating the seal structure of the hermetically closed space in a loading/unloading port of the inner chamber according to the first embodiment.

FIG. 14 is a vertical cross-sectional view schematically illustrating a partial configuration of a flange portion of the inner chamber and a sidewall of the outer chamber according to the first embodiment.

FIG. 15 is a vertical cross-sectional view schematically illustrating a configuration of a wafer processing apparatus according to a second embodiment.

FIG. 16 is a vertical cross-sectional view schematically illustrating the configuration of the wafer processing apparatus according to the second embodiment.

FIG. 17 is an explanatory view illustrating a gas system in the wafer processing apparatus according to the second embodiment.

FIG. 18 is a perspective view schematically illustrating configurations of a partition wall and a lifting mechanism according to the second embodiment.

FIG. 19 is a vertical cross-sectional view schematically illustrating configurations of the partition wall and the vicinity of the partition wall according to the second embodiment.

FIG. 20 is a horizontal cross-sectional view schematically illustrating configurations of the partition wall and the vicinity of the partition wall according to the second embodiment.

FIG. 21 is a vertical cross-sectional view schematically illustrating configurations of a chamber and the vicinity of the chamber according to the second embodiment.

### DETAILED DESCRIPTION

In a semiconductor device manufacturing process, various processes such as etching are performed on a semiconductor wafer (a substrate; hereinafter, referred to as a “wafer”) by using processing gases in a vacuum atmosphere (under a decompressed atmosphere).

In the related art, etching has been performed by using various methods. Particularly, in recent years, with the miniaturization of semiconductor devices, a method capable of finer etching called chemical oxide removal (COR) processing has been introduced in place of conventional etching techniques such as plasma etching and wet etching.

The COR processing is a process of supplying processing gases to the wafer inside a chamber maintained in a vacuum atmosphere and causing these gases to react with, for example, a film formed on the wafer, thereby producing a product. The product produced on the wafer surface by the COR processing is sublimated by performing heating processing in a subsequent operation, so that the film on the wafer surface is removed.

In the future, the frequency of using highly corrosive processing gases will increase in COR processing. In a substrate processing apparatus (a wafer processing apparatus), an inner surface of the chamber needs to be treated to have corrosion resistance against the processing gas. In addition, the inner surface of the chamber may also need to be treated differently in order to handle various processing gases. For example, as in the substrate processing apparatus disclosed in Patent Document 1 (a COR processing apparatus), an inner surface of the chamber is usually subjected to surface oxidation treatment, but in the case where a hydrogen fluoride gas is used, the inner surface of the chamber is made of Al or an Al alloy that has not been subjected to surface oxidation treatment.

However, since, for example, the conventional substrate processing apparatus disclosed in Patent Document 1 includes one chamber, it is necessary to replace the chamber every time a processing gas is changed. This chamber replacement is a task accompanied by a lot of loads, such as stopping of the entire system in which the substrate processing apparatus is placed, undocking of the substrate processing apparatus, and rerouting of gas supply lines, power supply lines, and water supply lines. Therefore, there is room for improvement in the conventional substrate processing apparatus, particularly in the configuration of the chamber.

A technique according to the present disclosure provides a substrate processing apparatus and a substrate processing method that are capable of handling various processing gases when processing a substrate by using the processing gases. Hereinafter, a wafer processing apparatus as a substrate processing apparatus and a wafer processing method as a substrate processing method according to embodiments of the present disclosure will be described with reference to the drawings. In the specification and drawings, elements having substantially the same functional configurations will be denoted by the same reference numerals and redundant descriptions thereof will be omitted.

### <Configuration of Wafer Processing Apparatus of First Embodiment>

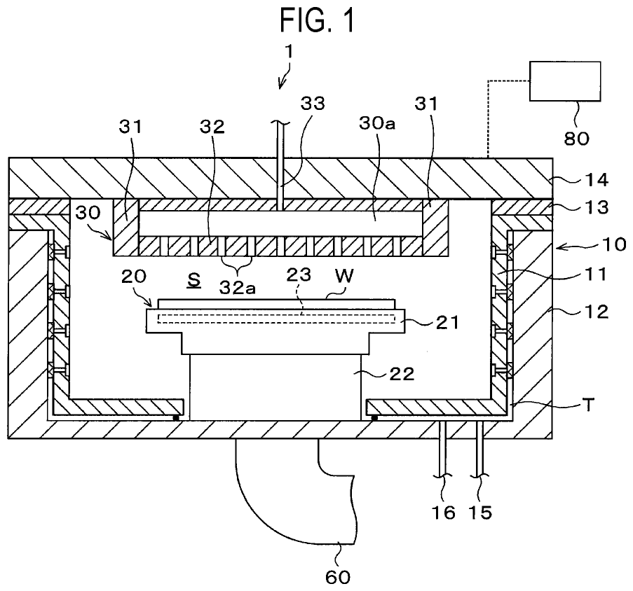

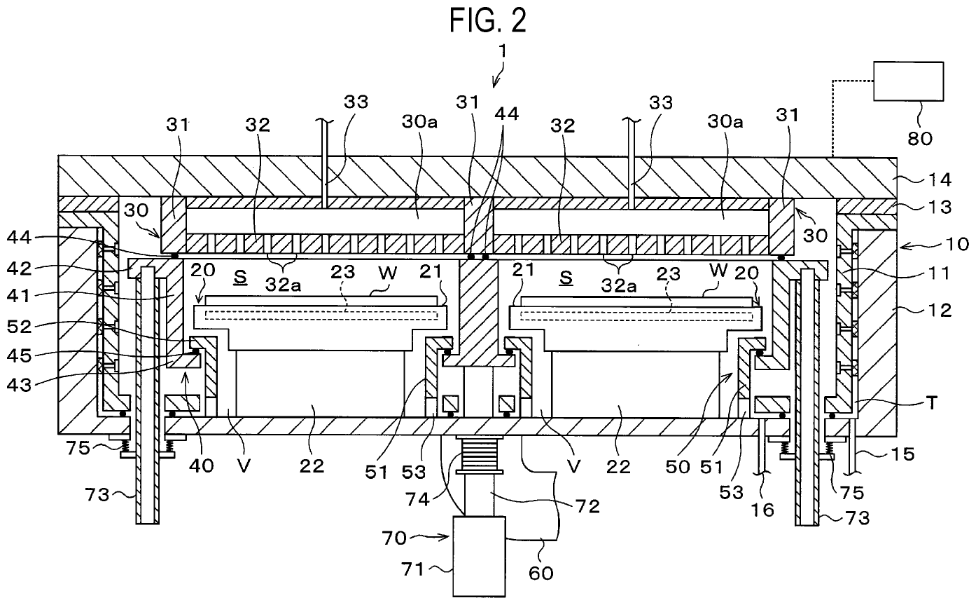

First, the configuration of a wafer processing apparatus according to a first embodiment will be described. FIGS. 1 and 2 are vertical cross-sectional views schematically illustrating the configuration of a wafer processing apparatus 1. In the present embodiment, a case where the wafer processing apparatus 1 is a COR processing apparatus which performs COR processing on a wafer W will be described as an example.

In the present embodiment, as will be described later, a chamber 10 is characterized by having a double structure, thereby implementing the wafer processing apparatus 1 which is configured to be adapted for various processing gases. Therefore, other structures of the wafer processing apparatus 1 may be designed arbitrarily. For example, as illustrated in FIG. 1, a single stage 20 for the wafer W, which will be described later, may be provided, or as illustrated in FIG. 2, two stages 20 may be provided. In addition, in the wafer processing apparatus 1 illustrated in FIG. 1, a partition wall 40, an inner wall 50, and a lifting mechanism 70, which will be described later, in the wafer processing apparatus 1 illustrated in FIG. 2 are omitted. The configuration of the wafer processing apparatus 1 illustrated in FIG. 2 will be described below, but the reference numbers of the constituent members of the wafer processing apparatus 1 illustrated in FIG. 2 correspond to those of the constituent members of the wafer processing apparatus 1 illustrated in FIG. 1.

As illustrated in FIG. 2, the wafer processing apparatus 1 includes a chamber 10. The chamber 10 has a double structure and includes an inner chamber 11 and an outer chamber 12. A hermetically closed space T (hereinafter, referred to as a “hermetically closed space T”) is defined between the inner chamber 11 and the outer chamber 12. A heater ring 13 that heats the inner chamber 11 is provided on a top surface of the inner chamber 11. In addition, on the top surface of the heater ring 13, a lid 14, which hermetically covers the top surface of the heater ring 13 to seal the interior of the inner chamber 11, may be provided. The outer chamber 12 is provided with an outer heater (not illustrated) that heats the outer chamber 12. The outer heater is provided at an arbitrary position. Detailed configurations of the chamber 10 and the vicinity of the chamber 10 will be described later.

The outer chamber 12 is provided with a gas supply pipe 15 that supplies an inert gas to the hermetically closed space T, and an intake pipe 16 that evacuates the hermetically closed space T. The gas supply pipe 15 and the intake pipe 16 are each provided at an arbitrary position in the outer chamber 12, for example, at the bottom plate. Details of a gas supply system that supplies the inert gas to the hermetically closed space T via the gas supply pipe 15 and a decompressing system (an exhaust system) that evacuates the hermetically closed space T via the intake pipe 16, will be described later.

Inside the inner chamber 11, a plurality of stages (two stages 20 in the present embodiment), on each of which the wafer W is placed, are provided. Each stage 20 has a substantially cylindrical shape, and includes an upper pedestal 21 having a placement surface on which the wafer W is placed, and a lower pedestal 22 fixed to the bottom plate of the outer chamber 12 and supporting the upper pedestal 21. The upper pedestal 21 includes, for example, an electrostatic chuck to attractively hold the wafer W. The upper pedestal 21 has a built-in temperature adjustment mechanism 23 that adjusts a temperature of the wafer W. The temperature adjustment mechanism 23 adjusts a temperature of the stage 20 by circulating a coolant such as water, and controls the temperature of the wafer W on the stage 20.

Although the stage 20 is fixed in the present embodiment, the stage 20 may be configured to be raised and lowered by a lifting mechanism (not illustrated).

A support pin unit (not illustrated) is provided on the bottom plate of the outer chamber 12 at a position below the stage 20. The wafer W is adapted to be delivered between support pins (not illustrated) that are driven upward and downward by this support pin unit and a transfer mechanism (not illustrated) provided outside the wafer processing apparatus 1.

A shower head 30 is provided on the bottom surface of the lid 14 to supply a processing gas to the interior of the inner chamber 11 (the wafer W placed on the stage 20). The shower heads 30 are provided individually above the stages 20, respectively.

Each shower head 30 includes, for example, a substantially cylindrical frame 31 of which the bottom surface is open and supported by the lower surface of the lid 14, and a substantially disk-shaped shower plate 32 fitted into the inner surface of the frame 31. The shower plate 32 is provided at a predetermined distance from a ceiling of the frame 31. As a result, a space 30a is defined between the ceiling of the frame 31 and the top surface of the shower plate 32. Further, the shower plate 32 is provided with a plurality of openings 32a that penetrate the shower plate 32 in the thickness direction. A gas supply pipe 33 is connected to the space 30a between the ceiling of the frame 31 and the shower plate 32. Details of the gas supply system that supplies a processing gas to the interior of the inner chamber 11 (the wafer W placed on the stage 20) via the shower head 30 and the gas supply pipe 33, will be described later.

A partition wall 40 configured to be raised and lowered is provided on the outer peripheries of the stages 20. The partition wall 40 includes two cylindrical portions 41 that individually surround the two stages 20, respectively, upper flange portions 42 provided at the upper ends of the cylindrical portions 41, and lower flange portions 43 provided at the lower ends of the cylindrical portions 41. The inner diameter of the cylindrical portions 41 is set to be larger than the outer surfaces of the stages 20, so that gaps are formed between the cylindrical portions 41 and the stages 20.

The partition wall 40 is provided with a heater (not illustrated) to be heated to a desired temperature. Due to this heating, foreign matter contained in the processing gas is prevented from adhering to the partition wall 40.

On the top surfaces of the upper flange portions 42, for example, seal members 44 such as resin O-rings are provided corresponding to respective stages 20 to hermetically closes the spaces between the upper flange portions 42 and the frames 31 when the upper flange portions 42 and the frames 31 are brought into contact with each other by raising the partition wall 40 by the lifting mechanism 70 to be described later. In addition, on protrusions 52 of inner walls 50 to be described later, seal members 45 such as O-rings are also provided corresponding to respective stages 20 to hermetically close the spaces between the protrusions 52 and the lower flange portions 43 when the protrusions 52 and the lower flange portions 43 are brought into contact with each other. In addition, by raising the partition wall 40, bringing the frames 31 and the seal members 44 into contact with each other, and bringing the lower flange portions 43 and the seal members 45 into contact with each other, processing spaces S surrounded by the stages 20, the partition wall 40, and the shower heads 30 are formed.

The inner walls 50 fixed to the bottom plate of the outer chamber 12 are provided at outer peripheries of the stages 20. Each inner wall 50 includes a substantially cylindrical main body 51 and a protrusion 52 that is provided at the upper end of the main body 51 and protrudes toward the outside of the inner wall 50. The inner walls 50 are arranged to individually surround the lower pedestals 22 of the stages 20, respectively. An inner diameter of the main bodies 51 of the inner walls 50 is set to be larger than an outer diameter of the lower pedestals 22, and exhaust spaces V are defined between the inner walls 50 and the lower pedestals 22, respectively. In the present embodiment, the exhaust spaces V also include spaces between the partition wall 40 and the upper pedestals 21. As illustrated in FIG. 2, the height of the inner walls 50 is set such that the seal members 45 and the protrusions 52 of the inner walls 50 are brought into contact with each other when the partition wall 40 is raised to the wafer processing position by the lifting mechanism 70 to be described later. As a result, the inner walls 50 and the partition wall 40 are brought into hermetic contact with each other.

A plurality of slits 53 are formed at the lower ends of the inner walls 50. The slits 53 are exhaust ports through which a processing gas is discharged. In the present embodiment, the slits 53 are formed at substantially equal intervals along the circumferential direction of each inner wall 50.

The inner walls 50 are fixed to the bottom plate of the outer chamber 12. As described above, the outer chamber 12 is configured to be heated by an outer heater (not illustrated), and the inner walls 50 are also heated by this outer heater. The inner walls 50 are heated to a desired temperature so that foreign matter contained in a processing gas does not adhere to the inner walls 50.

The outer chamber 12 is provided with an exhaust pipe 60 that exhausts the interior of the inner chamber 11. The exhaust pipe 60 is provided in the bottom plate of the outer chamber 12 outside the partition wall 40 and the inner walls 50. The exhaust pipe 60 is provided in common to the two inner walls 50. That is, the processing gases from the two exhaust spaces V are discharged from the common exhaust pipe 60. Details of the exhaust system that exhausts the interior of the inner chamber 11 via the exhaust pipe 60 will be described later.

The wafer processing apparatus 1 includes the lifting mechanism 70 that moves the partition wall 40 upward and downward, as described above. The lifting mechanism 70 includes an actuator 71 disposed outside the chamber 10, a drive shaft 72 connected to the actuator 71 and extending vertically upward within the inner chamber 11 through the bottom plates of the inner chamber 11 and the outer chamber 12, and a plurality of guide shafts 73 of which the tips are connected to the partition wall 40 and other ends extend to the outside of the outer chamber 12. The guide shafts 73 prevent the partition wall 40 from tilting when the partition wall 40 is raised or lowered by the drive shaft 72.

A lower end portion of an extendible bellows 74 is hermetically connected to the drive shaft 72. An upper end portion of the bellows 74 is hermetically connected to the bottom surface of the bottom plate of the outer chamber 12. Therefore, when the drive shaft 72 is raised and lowered, the bellows 74 expands and contracts in the vertical direction, so that the interior of the chamber 10 is hermetically maintained. In addition, between the drive shaft 72 and the bellows 74, for example, a sleeve (not illustrated) fixed to the bottom plate of the outer chamber 12 is provided to function as a guide during the raised and lowered operation.

An extendible bellows 75 is connected to each guide shaft 73 like the drive shaft 72. In addition, an upper end portion of the bellows 75 straddles the bottom plate and the sidewall of the outer chamber 12 and is hermetically connected to both the bottom plate and the sidewall of the outer chamber 12. Therefore, when the guide shafts 73 are raised and lowered following the raised and lowered operation of the partition wall 40 by the drive shaft 72, bellows 75 extend and contract in the vertical direction, so that the interior of the chamber 10 is hermetically maintained. Sleeves (not illustrated) that function as guides during the raised and lowered operation are also provided respectively between the guide shafts 73 and the bellows 75 as in the case of the drive shaft 72.

The wafer processing apparatus 1 described above is provided with a controller 80. The controller 80 is a computer including, for example, a CPU and memory, and includes a program storage (not illustrated). The program storage stores a program for controlling the processing of wafers W in the wafer processing apparatus 1. The programs may be recorded in a computer-readable storage medium (not illustrated) and may be installed in the controller 80 from the storage medium. In addition, the storage medium may be transitory or non-transitory.

### <Configuration of Gas System of First Embodiment>

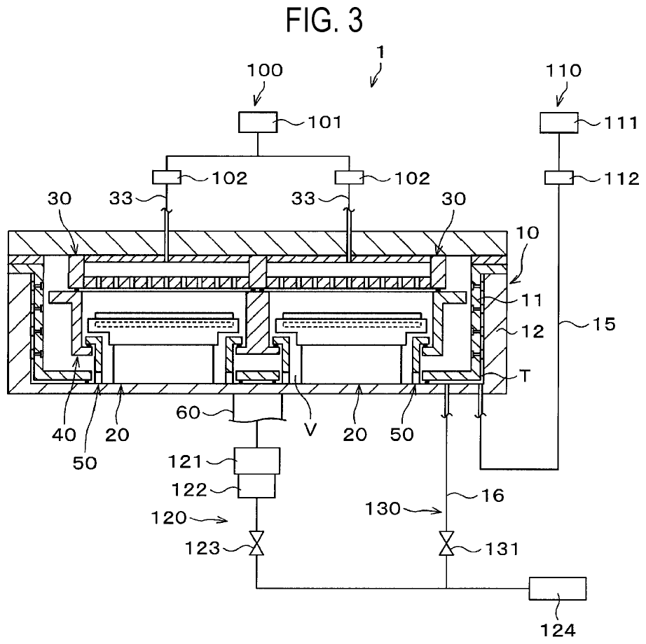

Next, a gas system in the above-described wafer processing apparatus 1 will be described. FIG. 3 is an explanatory view illustrating a gas system in the wafer processing apparatus 1. In the present embodiment, the wafer processing apparatus 1 includes a gas system (gas supply and exhaust) for the interior of the inner chamber 11 and a gas system (gas supply and decompression) for the hermetically closed space T between the inner chamber 11 and the outer chamber 12.

As illustrated in FIG. 3, a processing gas supplier 100, which supplies a processing gas to the interior of the inner chamber 11, includes the above-described shower head 30 and gas supply pipes 33. The gas supply pipes 33 are connected to a processing gas source 101 configured to be able to supply a processing gas. The processing gas is selected depending on a film to be etched. In addition, each gas supply pipe 33 is provided with a flow rate adjustment mechanism 102 that adjusts the supply amount of the processing gas, and is configured to be capable of individually controlling the amount of the processing gas to be supplied to each wafer W. In the processing gas supplier 100, the processing gas supplied from the processing gas source 101 is supplied toward the wafers W placed on respective stages 20 via the gas supply pipes 33 and the shower heads 30.

An inert gas supplier 110, which supplies an inert gas to the hermetically closed space T, includes the above-described gas supply pipe 15. The gas supply pipe 15 is connected to an inert gas source 111 configured to be capable of supplying an inert gas. As the inert gas, for example, a nitrogen gas, an argon gas, a helium gas, or the like is used. In addition, the gas supply pipe 15 is provided with a flow rate adjustment mechanism 112 configured to adjust the supply amount of the inert gas and is configured to be capable of controlling the amount of the inert gas to be supplied to the hermetically closed space T. In the inert gas supplier 110, the inert gas supplied from the inert gas source 111 is supplied to the hermetically closed space T via the gas supply pipe 15.

An exhauster 120, which exhausts the interior of the inner chamber 11, includes the above-described exhaust pipe 60. The exhaust pipe 60 is provided with a pressure regulating valve 121, a turbo molecular pump 122, and a valve 123, and a dry pump 124 is further connected to the exhaust pipe 60. In the exhauster 120, the dry pump 124 evacuates the internal pressure of the inner chamber 11 to about a medium vacuum, and the turbo molecular pump 122 evacuates the internal pressure of the inner chamber 11 to a high vacuum.

A decompressor 130, which evacuates the hermetically closed space T, has the above-described intake pipe 16. The intake pipe 16 is provided with a valve 131, and the dry pump 124 is further connected to the intake pipe 16. The decompressor 130 decompresses the hermetically closed space T to a desired degree of vacuum by the dry pump 124. By decompressing the hermetically closed space T to the desired degree of vacuum in this manner, it is possible to cause the hermetically closed space T to function as a vacuum heat insulating layer between the inner chamber 11 and the outer chamber 12, as described later.

In the present embodiment, the dry pump 124 is provided in common to the exhauster 120 and the decompressor 130. However, since the exhauster 120 is provided with the valve 123 and the decompressor 130 is provided with the valve 131, the exhaustion of the interior of the inner chamber 11 by the exhauster 120 and the decompression of the hermetically closed space T by the decompressor 130 can be controlled individually.

### <Configuration of Chamber of First Embodiment>

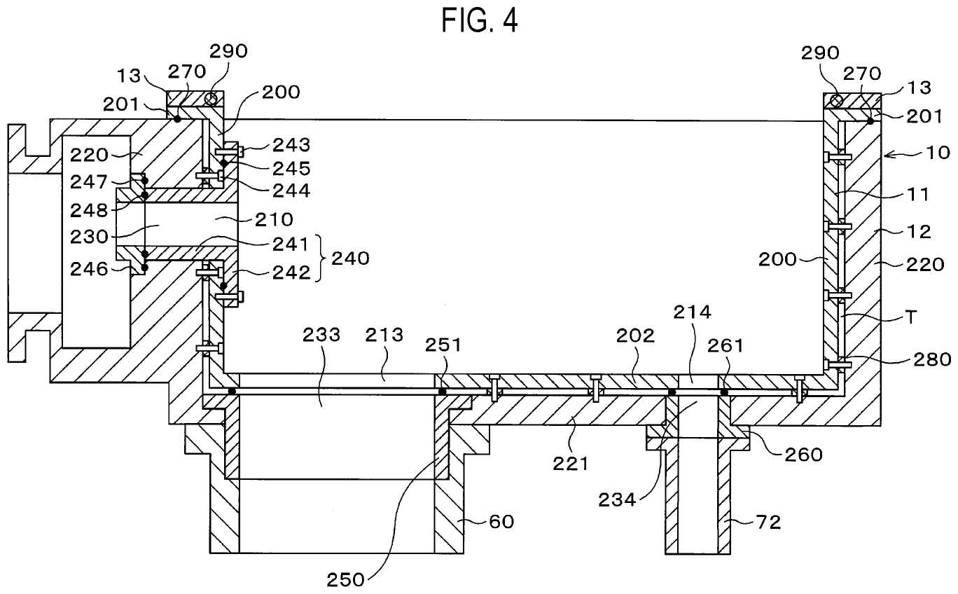

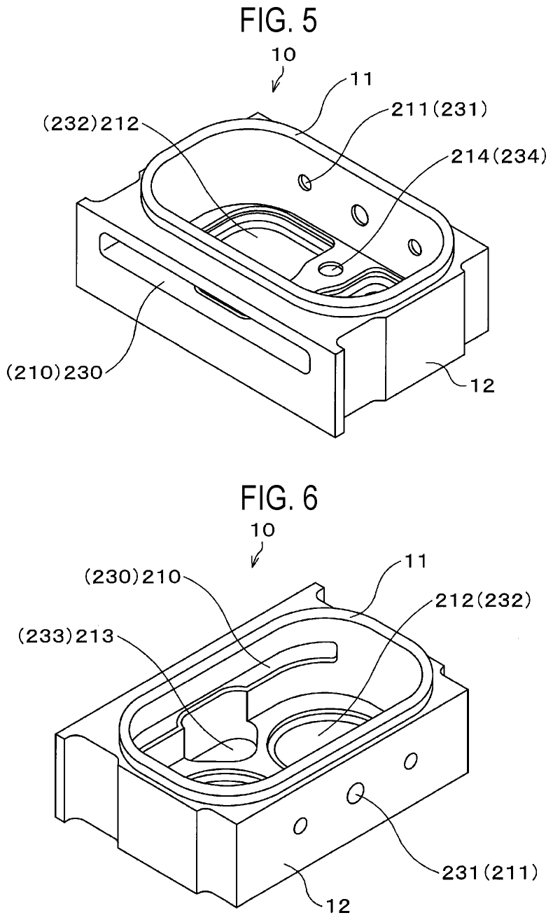

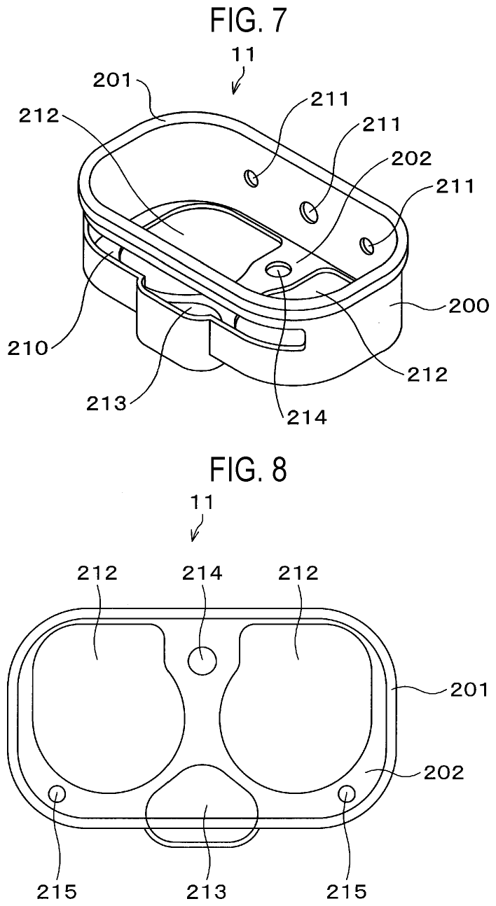

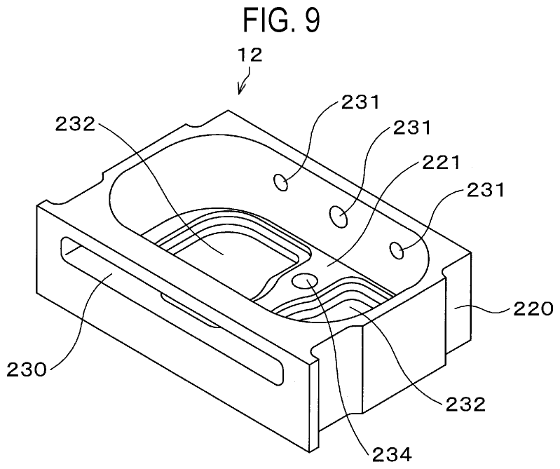

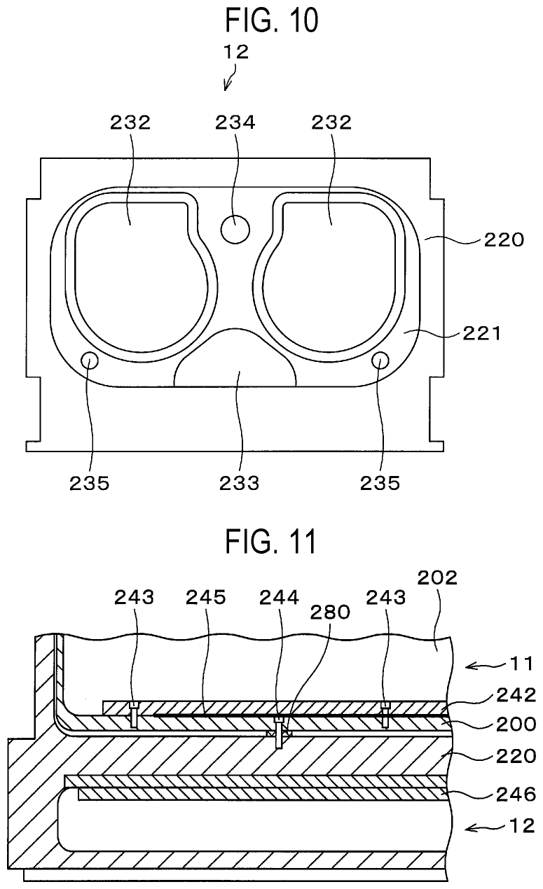

Next, configurations of the above-described chamber 10 and the vicinity of the chamber 10 will be described. FIG. 4 is a vertical cross-sectional view schematically illustrating configurations of the chamber 10 and the vicinity of the chamber 10. FIGS. 5 and 6 are perspective views schematically illustrating the configuration of the chamber 10. FIG. 7 is a perspective view schematically illustrating the configuration of the inner chamber 11, and FIG. 8 is a plan view schematically illustrating the configuration of the inner chamber 11. FIG. 9 is a perspective view schematically illustrating the configuration of the outer chamber 12, and FIG. 10 is a plan view schematically illustrating the configuration of the outer chamber 12. In FIGS. 4 to 10, illustration of the internal configuration of the inner chamber 11 is omitted to facilitate description of the configuration of the chamber 10. In FIGS. 4 to 10, illustration of the internal configuration of the inner chamber 11 is omitted to facilitate description of the configuration of the chamber 10.

### [Configuration of Inner Chamber and Outer Chamber]

As illustrated in FIGS. 4 to 6, the chamber 10 has a double structure and includes an inner chamber 11 and an outer chamber 12. The inner chamber 11 is configured to be detachable from the outer chamber 12. Specifically, the inner chamber 11 is adapted to be installable on and detachable from the upper portion of the outer chamber 12. When the inner chamber 11 is installed to the outer chamber 12, a hermetically closed space T is defined between the inner chamber 11 and the outer chamber 12. In addition, the outer chamber 12 is provided such that it is not to be exposed inside the inner chamber 11 and is provided such that it does not come into contact with a processing gas supplied to the interior of the inner chamber 11.

The inner chamber 11 illustrated in FIGS. 7 and 8 is made of metal such as aluminum or stainless steel. An inner surface of the inner chamber 11, i.e., a gas contact surface that comes into contact with the processing gas inside the inner chamber 11, is applied with a coating that is resistant to corrosion against the processing gas. This coating is determined depending on the type of the processing gas, and is, for example, nickel plating or the like.

The inner chamber 11 is a generally rectangular parallelepiped-shaped container with an open top surface. The inner chamber 11 includes a substantially cylindrical sidewall 200, a flange portion 201 protruding outward from the upper end of the sidewall 200, and a bottom plate 202 provided at the lower end of the sidewall 200 to cover an open bottom surface.

A loading/unloading port 210 for the wafer W is formed in one side surface of the sidewall 200. In addition, a plurality of (e.g., three) ports 211, are formed in the other side surface of the sidewall 200. The ports 211 are used for, for example, connecting members inside the inner chamber 11 and external devices.

The flange portion 201 is provided in an annular shape above the sidewall 220 (described later) of the outer chamber 12. The outer surface of the flange portion 201 is exposed to the outside of the wafer processing apparatus 1.

A plurality of openings 212 to 215 are provided in the bottom plate 202. The openings 212 are used for installing the stages 20 and the inner walls 50 and provided at two locations in the bottom plate 202. The opening 213 is used for inserting the exhaust pipe 60 therethrough. The opening 214 is used for inserting the drive shaft 72 therethrough. The openings 215 are used for inserting the guide shafts 73 therethrough and provided at two locations on the bottom plate 202.

The outer chamber 12 illustrated in FIGS. 9 and 10 is made of metal such as aluminum or stainless steel. As described above, since the outer chamber 12 is provided such that it does not come into contact with the processing gas supplied into the inner chamber 11, the surface of the outer chamber 12 is not applied with a coating. That is, the outer chamber 12 is made of solid metal.

The outer chamber 12 is a generally rectangular parallelepiped-shaped container with an open top surface. The outer chamber 12 includes a substantially cylindrical sidewall 220 and a bottom plate 221 provided at the lower end of the sidewall 220 to cover the bottom surface of the opening.

A loading/unloading port 230 for the wafer W is provided in one side surface of the sidewall 220 at a position corresponding to the above-described loading/unloading port 210. In addition, on the other side surface of the sidewall 220, a plurality of (e.g., three) ports 231 are formed at positions corresponding to the above-described ports 211.

A plurality of openings 232 to 235 are formed in the bottom plate 221. These openings 232 to 235 are provided at positions corresponding to the above-described openings 212 to 215, respectively.

### [Configuration of Hermetically Closed Space]

As illustrated in FIG. 4, the hermetically closed space T is defined between the inner chamber 11 and the outer chamber 12. The hermetically closed space T is defined between the sidewall 200 and the sidewall 220, between the flange portion 201 and the sidewall 220, and between the bottom plate 202 and the bottom plate 221. The hermetically closed space T is sealed and hermetically closed by using a plurality of adapters and a plurality of seal members, which will be described later. The seal structures of this hermetically closed space T will be described below.

The adapters connect the inner chamber 11 and the outside of the inner chamber 11 (e.g., the outer chamber 12, and the like) when the inner chamber 11 is installed in the outer chamber 12. In addition, the adapters may be installed from inside of the inner chamber 11 or from outside of the inner chamber 11 depending on the installation positions thereof. The adapters are made of metal such as aluminum or stainless steel, and surfaces of the adapters, i.e., the gas contact surfaces that come into contact with the processing gas inside the inner chamber 11, are applied with a coating that is resistant to corrosion against the processing gas. In addition, as the seal members, for example, resin O-rings are used.

First, a seal structure of the hermetically closed space T in the loading/unloading ports 210 and 230 for the wafers W will be described. An adapter 240 is provided in the loading/unloading port 210 of the inner chamber 11. The adapter 240 connects the sidewall 200 of the inner chamber 11 and the sidewall 220 of the outer chamber 12. The adapter 240 has a substantially cylindrical main body 241 having opposite open end surfaces, and an engagement portion 242 which protrudes outward from the main body 241. The main body 241 extends horizontally from the loading/unloading port 210 to the loading/unloading port 230 along the inner surfaces of the loading/unloading ports 210 and 230. The engagement portion 242 extends vertically along the sidewall 200 of the inner chamber 11.

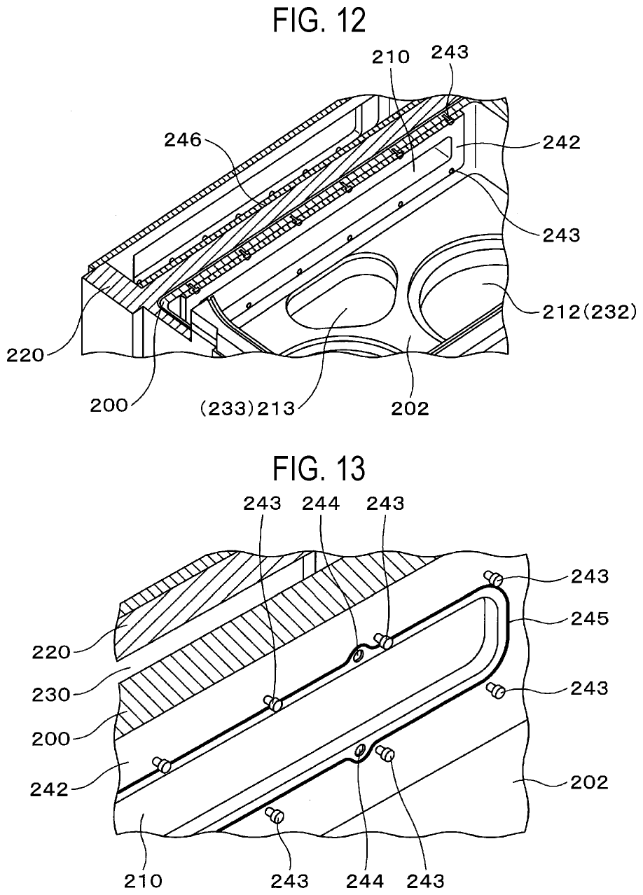

FIGS. 11 to 13 are explanatory views illustrating the seal structure of the hermetically closed space T in the loading/unloading port 210 of the inner chamber 11. In FIG. 13, illustration of the adapter 240 is omitted in order to describe the configuration of the sidewall 200 of the inner chamber 11. As illustrated in FIGS. 11 to 13, the sidewall 200 of the inner chamber 11 and the engagement portion 242 of the adapter 240 are fastened together by a plurality of first fastening members 243. In addition, the sidewall 200 of the inner chamber 11 and the sidewall 220 of the outer chamber 12 are fastened together by a plurality of second fastening members 244. For example, screws are used for these fastening members 243 and 244.

A seal member 245 is provided between the inner surface of the sidewall 200 of the inner chamber 11 and the side surface of the engagement portion 242 of the adapter 240. The seal member 245 is provided in an annular shape to surround the loading/unloading port 210.

The first fastening members 243 are provided outside the seal member 245. Here, when the first fastening members 243 is fastened from the engagement portion 242 of the adapter 240 to the sidewall 220 of the outer chamber 12, the processing gas inside the inner chamber 11 leaks into the hermetically closed space T through the gap between each first fastening member 243 and its screw hole. Therefore, in order to prevent the processing gas from leaking into the hermetically closed space T and coming into contact with the sidewall 220 of the outer chamber 12, in the present embodiment, the first fastening members 243, which fasten the inner chamber 11 and the adapter 240 together, are provided outside the seal member 245.

In addition, the second fastening members 244 are provided inside the seal member 245. Here, when the second fastening members 244 are provided outside the seal member 245, the second fastening members 244 communicates with the interior of the inner chamber 11, so that the processing gas inside the inner chamber 11 leaks into the hermetically closed space T through the gap between each second fastening member 244 and its screw hole. Therefore, in order to prevent the processing gas from leaking into the hermetically closed space T and coming into contact with the sidewall 220 of the outer chamber 12, in the present embodiment, the second fastening members 244 are provided inside the seal member 245.

In addition, in the example of FIG. 13, the seal member 245 is provided in a curved form near the second fastening members 244 to avoid interference with the second fastening member 244, but the layout of the seal member 245 is not limited thereto. For example, when the second fastening members 244 are provided further inside (at positions closer to the loading/unloading port 210) than in the example illustrated in FIG. 13, the curving of the seal member 245 may be omitted.

In addition, a single seal member 245 is provided in the present embodiment, but a plurality of seal members 245 may be provided. For example, in addition to the seal member 245 provided in an annular shape to surround the loading/unloading port 210, seal members (not illustrated), which individually surround the outer peripheries of respective second fastening members 244, may be provided.

As illustrated in FIG. 4, an adapter 246 is provided in the loading/unloading port 230 of the outer chamber 12. This adapter 246 is fastened to the sidewall 220 of the outer chamber 12 by, for example, fastening members (not illustrated) such as screws. A seal member 247 is provided between the adapter 246 and the sidewall 220. In addition, a seal member 248 is also provided between the adapter 246 on the outer side and the adapter 240 on the inner side. These seal members 247 and 248 are each provided in an annular shape to surround the loading/unloading port 230.

With the above seal structure, the hermetically closed space T is sealed in the loading/unloading ports 210 and 230, so that the processing gas inside the inner chamber 11 is prevented from leaking into the hermetically closed space T.

Next, the seal structure of the hermetically closed space T in the openings 213 and 233 (the portion where the exhaust pipe 60 is connected) will be described. An adapter 250 is provided in the openings 213 and 233. The adapter 250 connects the bottom plate 202 of inner chamber 11 and the bottom plate 221 of outer chamber 12. The adapter 250 extends vertically from the bottom plate 221 of the outer chamber 12 to the exhaust pipe 60.

A seal member 251 is provided between the bottom surface of the bottom plate 202 of the inner chamber 11 and the top surface of the adapter 250. The seal member 251 is provided in an annular shape to surround the openings 213 and 233.

With the above seal structure, the hermetically closed space T is sealed in the openings 213 and 233, so that the processing gas inside the inner chamber 11 is prevented from leaking into the hermetically closed space T.

Next, the seal structure of the hermetically closed space T in the openings 214 and 234 (the portions where the drive shaft 72 is connected) will be described. An adapter 260 is provided in the openings 214 and 234. The adapter 260 connects the bottom plate 202 of inner chamber 11 and the bottom plate 221 of outer chamber 12. The adapter 260 extends vertically from the bottom plate 221 of the outer chamber 12 to the drive shaft 72.

A seal member 261 is provided between the bottom surface of the bottom plate 202 of the inner chamber 11 and the top surface of the adapter 260. The seal member 261 is provided in an annular shape to surround the openings 214 and 234.

With the above seal structure, the hermetically closed space T is sealed in the openings 214 and 234, so that the processing gas inside the inner chamber 11 is prevented from leaking into the hermetically closed space T.

In addition, the seal structure of the hermetically closed space T in the other openings 212 and 232 (the portions where the stages 20 and the inner walls 50 are installed), the seal structure of the hermetically closed space T in the openings 215 and 235 (the portions where the guide shafts 73 are connected), and the seal structure of the hermetically closed space T in the ports 211 and 231 are the same as the above-described seal structures. That is, each opening is provided with an adapter and a seal member.

Next, the seal structure of the hermetically closed space T between the flange portion 201 and the top surface of the sidewall 220 will be described. A seal member 270 is provided between the bottom surface of the flange portion 201 and the top surface of the sidewall 220. The hermetically closed space T is sealed to prevent external atmosphere from flowing into the hermetically closed space T.

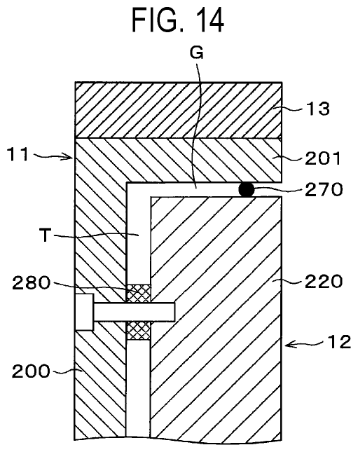

As illustrated in FIG. 14, a gap G is formed between the bottom surface of the flange portion 201 and the top surface of the sidewall 220. This gap is capable of suppressing heat transfer between the inner chamber 11 and the outer chamber 12. Here, as described above, the hermetically closed space T is decompressed to a desired degree of vacuum by the decompressor 130, and the hermetically closed space T functions as a vacuum insulating layer between the inner chamber 11 and the outer chamber 12. In the present embodiment, the heat transfer between the inner chamber 11 and the outer chamber 12 is suppressed by the gap G, so that the function of the vacuum heat insulating layer of the hermetically closed space T can be maintained.

As described above, the hermetically closed space T is sealed and hermetically closed by using a plurality of adapters and a plurality of seal members, which will be described later. Therefore, the processing gas inside the inner chamber 11 does not leak into the hermetically closed space T, and as a result, the outer chamber 12 to the processing gas is suppressed from being exposed to the processing gas.

A plurality of spacers 280 are provided in the hermetically closed space T. The spacers 280 are in contact with inner chamber 11 and outer chamber 12. The spacers 280 are made of, for example, stainless steel. These spacers 280 allow the strength of the inner chamber 11 to be maintained. In other words, by providing the spacers 280, it is also possible to reduce the thickness of the inner chamber 11. The installation positions of the spacers 280 are arbitrary. For example, the spacers 280 may be installed at locations where the strength of the inner chamber 11 is weak.

### [Configuration of Heater]

As illustrated in FIG. 4, a heater ring 13 configured to heat the inner chamber 11 is provided on the top surface of the flange portion 201 of the inner chamber 11. The heater ring 13 is provided in an annular shape. The heater ring 13 is exposed to the outside. In addition, the interior of the heater ring 13 is maintained at atmospheric pressure, and the heater ring 13 includes an inner heater 290 such as a sheath heater or a cartridge heater. The outer chamber 12 is provided with an outer heater (not illustrated) configured to heat the outer chamber 12. The outer heater is provided at an arbitrary position. These inner heater 290 and outer heater are individually controlled and are adjustable to individual temperatures, respectively.

The inner heater 290 (the heater ring 13) adjusts the temperature of the inner chamber 11 to, for example, 120 degrees C. to 140 degrees C. As a result, for example, foreign matter contained in the processing gas can be suppressed from adhering to the inner chamber 11.

In addition, as described above, the hermetically closed space T is decompressed to a desired degree of vacuum by the decompressor 130, so that the hermetically closed space T functions as a vacuum insulating layer between the inner chamber 11 and the outer chamber 12. The hermetically closed space T, which is a vacuum heat insulating layer, may allow the inner chamber 11 to be thermally independent and may efficiently adjust the temperature of the inner chamber 11.

The outer heater adjusts the temperature of the outer chamber 12 to, for example, 100 degrees C. or lower. Here, the inner chamber 11 is thermally independent by the hermetically closed space T, which is a vacuum insulating layer, but there is some heat transfer between the inner chamber 11 and the hermetically closed space T. In particular, since the volume of the outer chamber 12 is large and the outer chamber 12 is connected to a wafer transfer device or the like outside the wafer processing apparatus 1, some heat from the inner chamber 11 escapes via the outer chamber 12. Therefore, in the present embodiment, the temperature of the inner chamber 11 is appropriately controlled by adjusting the temperature of the outer chamber 12 in advance. That is, the outer heater functions as an assist for temperature adjustment of the inner chamber 11.

The temperature of the outer chamber 12, which is adjusted by the outer heater, is arbitrary. However, the temperature of the inner chamber 11 is controlled to be higher than the temperature of the outer chamber 12. For example, when the chamber has a single structure as in the wafer processing apparatus disclosed in Patent Document 1, the temperature of the chamber is adjusted to, for example, 120 degrees C. to 150 degrees C. In this regard, in the wafer processing apparatus 1 of the present embodiment, since the chamber 10 has a double structure, the temperature of the outer chamber 12 can be kept lower than in the conventional case.

### <Wafer Processing Method of First Embodiment>

Next, wafer processing (COR processing) in the wafer processing apparatus 1 configured as described above will be described.

First, in the state in which the partition wall 40 is lowered to the retracted position, wafers W are transferred into the chamber 10 (the inner chamber 11) by a transfer mechanism (not illustrated) provided outside the wafer processing apparatus 1 and placed on respective stages 20.

Thereafter, the partition wall 40 is raised to the wafer processing position. As a result, the processing spaces S are formed by the partition wall 40.

Then, the interior of the inner chamber 11 is exhausted to a desired pressure by the exhauster 120, and a processing gas is supplied to the interior of the inner chamber 11 from the processing gas supplier 100, and COR processing is performed on the wafers W. In addition, the processing gas in the processing spaces S passes through the exhaust space V and the slits 53 in each inner wall 50 and is discharged from the exhauster 120.

During the COR processing, the temperature of the inner chamber 11 is adjusted to, for example, 120 degrees C. to 150 degrees C. by the inner heater 290 (the heater ring 13), and the temperature of the outer chamber 12 is adjusted to, for example, 80 degrees C. or lower by the outer heater. In addition, the hermetically closed space T is decompressed to a desired degree of vacuum by the decompressor 130 such that the hermetically closed space functions as a vacuum insulating layer between the inner chamber 11 and the outer chamber 12. As a result, the temperature of the inner chamber 11 may be efficiently controlled by the vacuum heat insulating layer.

In addition, in order to adjust a pressure in the hermetically closed space T during the COR processing, an inert gas may be supplied to the hermetically closed space T from the inert gas supplier 110. For example, when a pressure difference occurs between the interior of the inner chamber 11 and the hermetically closed space T, an inert gas is supplied from the inert gas supplier 110 to the hermetically closed space T in order to adjust this pressure difference. Specifically, in order to suppress the processing gas from flowing into the hermetically closed space T, the pressure in the hermetically closed space T is adjusted such that the pressure inside the inner chamber 11 does not become higher than that of the hermetically closed space T. Alternatively, for example, the pressure in the hermetically closed space T is monitored with a pressure gauge (not illustrated), and the inert gas is supplied to the hermetically closed space T from the inert gas supplier 110 when the pressure becomes lower than a threshold value.

When the COR processing is terminated, the partition wall 40 is lowered to the retracted position, and the wafers W on respective stages 20 are carried out to the outside of the wafer processing apparatus 1 by the wafer transfer mechanism (not illustrated). Thereafter, the wafers W are heated by a heating device provided outside the wafer processing apparatus 1, and a reaction product produced by the COR processing is vaporized and removed. As a result, a series of COR processing is terminated.

### <Maintenance of Wafer Processing Apparatus of First Embodiment>

Next, maintenance of the wafer processing apparatus 1 will be described. In this maintenance, for example, the inner chamber 11 is replaced. Replacing the inner chamber 11 includes changing the corrosion-resistant coating of the inner chamber 11, for example, when changing the processing gas. Alternatively, for example, after performing COR processing on a plurality of wafers W, the inner chamber 11 that has deteriorated over time may be replaced.

First, the evacuation of the hermetically closed space T by the decompressor 130 is stopped, and the inert gas is supplied into the hermetically closed space T from the inert gas supplier 110. The inert gas is supplied until the interior of the hermetically closed space T reaches atmospheric pressure.

Thereafter, after removing the lid 14 and opening the interior of the inner chamber 11 to the air, the inner chamber 11 is replaced. Then, after forming the hermetically closed space T between the inner chamber 11 and the outer chamber 12, the hermetically closed space Tis decompressed to a desired degree of vacuum by the decompressor 130. In this way, preparation for COR processing is completed.

### [Effect of First Embodiment]

According to the first embodiment described above, since the chamber 10 has a double structure, even when it is necessary to change the coating on the surface of the chamber due to a change in the gas type of a processing gas, this can be done simply by replacing the inner chamber 11. In other words, there is no need to replace the outer chamber 12. For this reason, it is possible to reduce the loads at the time of replacing the chamber as in the conventional wafer processing apparatus, such as stopping of the entire system in which the substrate processing apparatus is placed, undocking of the substrate processing apparatus, and rerouting of gas supply lines, power supply lines, and water supply lines. In this way, the wafer processing apparatus 1 is configured to be capable of handling various processing gases (various gas processes) in a simple manner.

In addition, according to the present embodiment, the outer chamber 12 does not come into contact with the processing gas supplied into the inner chamber 11. Therefore, there is no need to apply a corrosion-resistant coating to the surface of the outer chamber 12, and the outer chamber 12 can be made of solid metal.

In addition, according to the present embodiment, the hermetically closed space T is provided between the inner chamber 11 and the outer chamber 12, and this hermetically closed space T is sealed and hermetically closed with a plurality of adapters and a plurality of seal members. In particular, in the loading/unloading ports 210 and 230 for wafers W, a first fastening member 243, which fastens the inner chamber 11 and the adapter 240 together, is provided outside the seal member 245, and second fastening members 244, which fasten the inner chamber 11 and the outer chamber 12 together, are provided inside the seal member 245. Therefore, a processing gas can be suppressed from flowing into the hermetically closed space T through the screw holes of the first fastening members 243 and the second fastening members 244, and the hermetically closed space T can be reliably sealed. As described above, the sealing performance of the hermetically closed space T can be ensured with a simple structure.

In addition, according to the present embodiment, the hermetically closed space T is decompressed to a desired degree of vacuum by the decompressor 130, so that the hermetically closed space T functions as a vacuum insulating layer between the inner chamber 11 and the outer chamber 12. In addition, a gap G is provided between the bottom surface of the flange portion 201 of the inner chamber 11 and the top surface of the sidewall 220 of the outer chamber 12, and the inner chamber 11 and the outer chamber 12 are not in contact with each other at other locations as well, so that the vacuum insulating layer function of the hermetically closed space T can be maintained. Therefore, since the inner chamber 11 can be made thermally independent, the temperature of the inner chamber 11 can be efficiently adjusted. As a result, the load on the inner heater 290 can be reduced.

In addition, according to the present embodiment, the pressure in the hermetically closed space T can be adjusted by the inert gas supplier 110. Therefore, during wafer processing, the pressure difference between the interior of the inner chamber 11 and the hermetically closed space T can be suppressed, and the processing gas can be suppressed from flowing into the hermetically closed space T. In addition, even when replacing the inner chamber 11, the inert gas can be supplied from the inert gas supplier 110 to the hermetically closed space T to bring the interior of the hermetically closed space T to atmospheric pressure, and the inner chamber 11 can be smoothly replaced.

In addition, according to the present embodiment, the evacuation of the interior of the inner chamber 11 by the exhauster 120 and the decompression of the hermetically closed space T by the decompressor 130 can be individually controlled. Therefore, each of the pressure inside the inner chamber 11 and the pressure in the hermetically closed space T can be adjusted appropriately.

In addition, according to the present embodiment, the temperature of the inner chamber 11 by the inner heater 290 (the heater ring 13) and the temperature of the outer chamber 12 by the outer heater can be controlled individually. Therefore, the temperature of the inner chamber 11 and the temperature of the outer chamber 12 can be adjusted appropriately.

In particular, in the present embodiment, since the chamber 10 has a double structure including the hermetically closed space T, the temperature of the outer chamber 12 can be kept lower than the temperature of the inner chamber 11. Therefore, the load on the outside heater can be reduced. In addition, for example, the time from taking heat out of the wafer processing apparatus 1 to performing maintenance can be shortened, and furthermore, the time from when the wafer processing apparatus 1 is returned to normal operation after the maintenance can also be shortened.

In addition, in the above-described embodiment, the wafer processing apparatus 1 in which two stages 20 are provided as illustrated in FIG. 2 has been described, but the above-described effects can also be achieved with the wafer processing apparatus 1 in which a single stage 20 is provided as illustrated in FIG. 1.

In addition, for example, in the above-described embodiment, the description has been made based on an example in which one or two stages 20 are provided, but the number of stages 20 to be installed is not limited thereto. For example, the number of stages 20 may be three or more.

### <Configuration of Wafer Processing Apparatus of Second Embodiment>

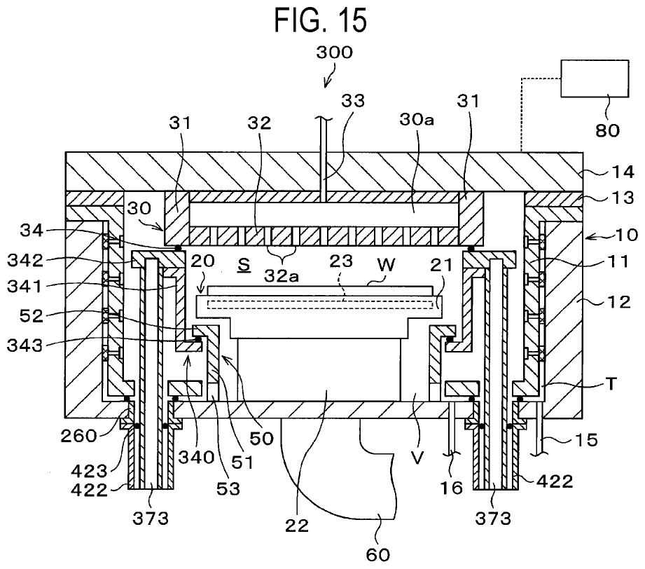

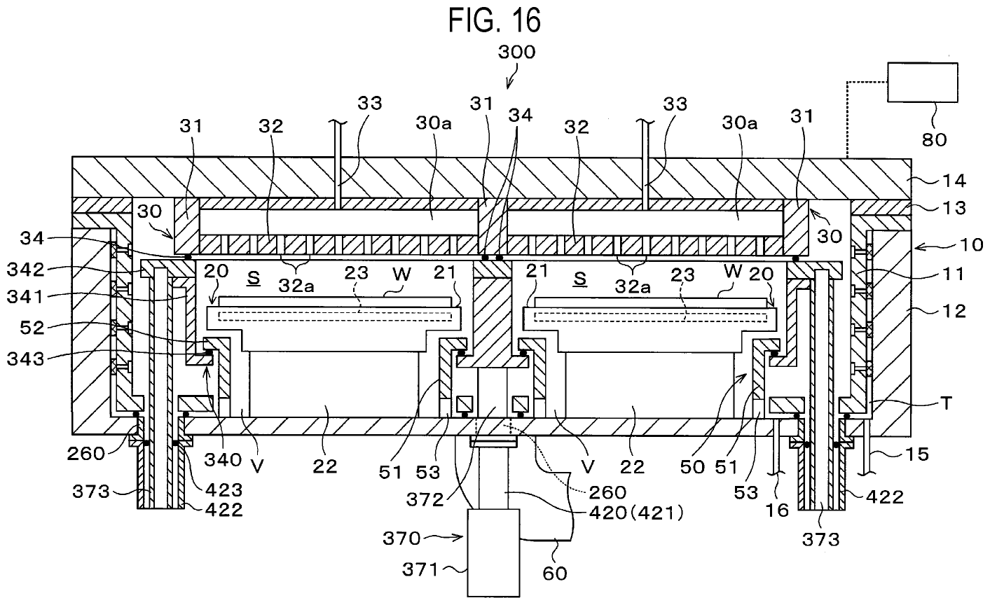

Next, a configuration of a wafer processing apparatus according to a second embodiment will be described. FIGS. 15 and 16 are vertical cross-sectional views schematically illustrating a configuration of a wafer processing apparatus 300. In the configuration of the wafer processing apparatus 300 of the second embodiment, the same components as those of the wafer processing apparatus 1 of the first embodiment are denoted by the same reference numerals and a redundant description thereof will be omitted.

The present embodiment is characterized in that the wafer processing apparatus 300 has a triple structure since the chamber 10 has a double structure and a partition wall 340 is provided inside the chamber 10. With this triple structure, the wafer processing apparatus 300 which is configured to be adapted for various processing gases is implemented. Therefore, other structures of the wafer processing apparatus 300 may be designed arbitrarily. For example, as illustrated in FIG. 15, a single stage 20 for the wafer W, which will be described later, may be provided, or as illustrated in FIG. 16, two stages 20 may be provided.

In addition, even if the wafer processing apparatus 300 includes a single stage 20 as illustrated in FIG. 15, the partition wall 340, the inner wall 50, and the lifting mechanism 370 are provided. In such a case, a processing space S surrounded by the stage 20, the partition wall 340, and the shower head 30 is formed, the flow of a processing gas in the processing space S can be made uniform, and the exhaust path from the processing space S can also be controlled. In addition, no matter what shape the chamber 10 has, a processing space S having a substantially circular shape in a plan view is formed by the partition wall 340, and stable etching processing can be performed in the processing space S. In addition, since the volume of the processing space S is smaller than the internal space of the chamber 10, the amount of the processing gas to be supplied can also be reduced.

The configuration of the wafer processing apparatus 300 illustrated in FIG. 16 will be described below, but the reference numbers of the constituent members of the wafer processing apparatus 300 illustrated in FIG. 16 correspond to those of the constituent members of the wafer processing apparatus 300 illustrated in FIG. 15.

As in the wafer processing apparatus 1 of the first embodiment, the wafer processing apparatus 300 illustrated in FIG. 16 includes a chamber 10, an inner chamber 11, an outer chamber 12, a hermetically closed space T, a heater ring 13, a lid 14, a gas supply pipe 15, an intake pipe 16, stages 20, upper pedestals 21, lower pedestals 22, temperature adjustment mechanisms 23, shower heads 30, a spaces 30a, frames 31, shower plates 32, openings 32a, and gas supply pipes 33.

Seal members 34 are provided on the bottom surfaces of the shower heads 30, specifically on the bottom surfaces of the frames 31. For the seal members 34, for example, resin lip seals are used. These seal members 34 hermetically close the spaces between the heater plate 342 and the frames 31 when the heater plate 342 of the partition wall 340 and the frames 31 come into contact with each other when the partition wall 340 is raised by the lifting mechanism 370. The seal members 34 are provided corresponding to the stages 20, respectively. In addition, the seal members 34 are provided in place of the seal members 44 in the wafer processing apparatus 1 of the first embodiment.

A partition wall 340 configured to be raised and lowered is provided on the outer peripheries of the stages 20. The partition wall 340 includes two sub-partition walls 341, which individually surround the two stages 20, respectively, and a heater plate 342, which is provided on the top surfaces of the sub-partition walls 341. The inner diameter of sub-partition walls 341 are set to be larger than the outer surfaces of the stages 20, so that gaps are formed between the sub-partition walls 341 and the stages 20. The detailed configuration of the partition wall 340 will be described later. In addition, the partition wall 340 is provided in place of the partition wall 40 in the wafer processing apparatus 1 of the first embodiment.

As described above, the seal members 34 provided on the frames 31 hermetically close the spaces between the frames 31 and the heater plate 342 when the frames 31 and the heater plate 342 come into contact with each other. In addition, on the protrusions 52 of the inner walls 50, seal members 343, such as resin O-rings, which hermetically close the spaces between the protrusions 52 and the sub-partition walls 341 when the protrusions 52 and the sub-partition walls 341 (the lower flange portions 402 to be described later) come into contact with each other, are provided corresponding to the stages 20, respectively. In addition, the seal members 343 are provided in place of the seal members 45 in the wafer processing apparatus 1 of the first embodiment. In addition, by raising the partition wall 340, bringing the heater plates 342 and the seal members 34 into contact with each other, and bringing the flange portions 402 on the lower side and the seal members 343 into contact with each other, processing spaces S surrounded by the stages 20, the partition wall 340, and the shower heads 30 are formed.

As in the wafer processing apparatus 1 of the first embodiment, the wafer processing apparatus 300 includes inner walls 50, main bodies 51, protrusions 52, exhaust spaces V, and slits 53. As illustrated in FIG. 16, the height of the inner walls 50 is set such that the seal members 343 provided on the protrusions 52 and the lower flange portions 402 of the sub-partition walls 341 come into contact with each other when the partition wall 340 is raised to the wafer processing position by a lifting mechanism 370, which will be described later. As a result, the inner walls 50 and the partition wall 340 are brought into hermetic contact with each other.

The inner walls 50 are fixed to the bottom plate of the outer chamber 12. In addition, the outer chamber 12 is configured to be heated by an outer heater 291, which will be described later, and the inner walls 50 are also heated by the outer heater 291. The inner walls 50 are heated to a desired temperature so that foreign matter contained in a processing gas does not adhere to the inner walls 50.

Like the wafer processing apparatus 1 of the first embodiment, the wafer processing apparatus 300 includes an exhaust pipe 60. The exhaust pipe 60 exhausts the interior of the partition wall 340 and the interior of the inner chamber 11. In the bottom plate of the outer chamber 12, the exhaust pipe 60 is provided inside the inner chamber 11 and outside the partition wall 340 and the inner walls 50.

As described above, the wafer processing apparatus 300 includes a lifting mechanism 370 that raises and lowers the partition wall 340. The lifting mechanism 370 includes an actuator 371 disposed outside the chamber 10, a drive shaft 372 connected to the actuator 371 and extending vertically upward within the inner chamber 11 through the bottom plates of the inner chamber 11 and the outer chamber 12, and a plurality of (e.g., two) guide shafts 373, of which the tips are connected to the partition wall 340 and the other base ends extend to the outside of the outer chamber 12. The guide shafts 373 prevent the partition wall 340 from tilting when the partition wall 340 is raised or lowered by the drive shaft 372. The detailed configuration of the lifting mechanism 370 will be described later.

Like the wafer processing apparatus 1 of the first embodiment, the wafer processing apparatus 300 includes a controller 80.

### <Configuration of Gas System of Second Embodiment>

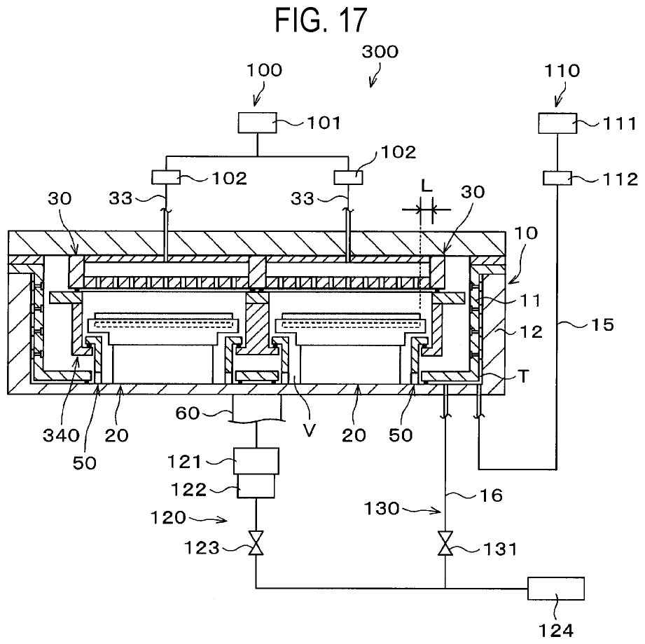

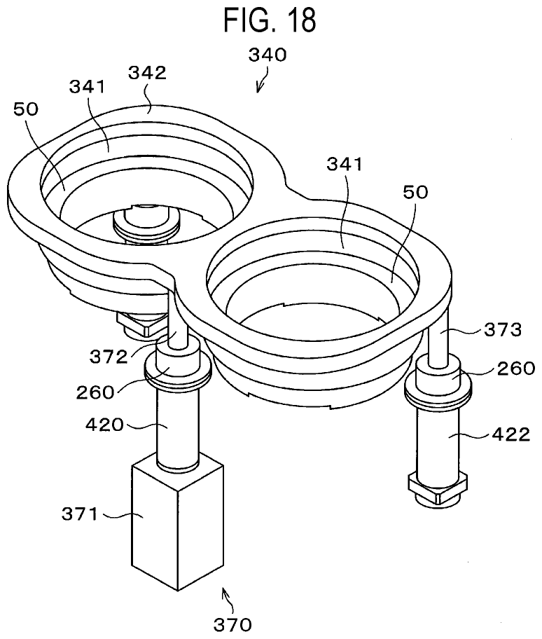

Next, a gas system in the above-described wafer processing apparatus 300 will be described. FIG. 17 is an explanatory view illustrating the gas system in the wafer processing apparatus 300. The gas system in the wafer processing apparatus 300 is the same as the gas system in the wafer processing apparatus 1 of the first embodiment. As illustrated in FIG. 17, the gas system in the wafer processing apparatus 300 includes a processing gas supplier 100, a processing gas source 101, a flow rate adjustment mechanism 102, an inert gas supplier 110, an inert gas source 111, and a flow rate adjustment mechanism 112, an exhauster 120, a pressure regulating valve 121, a turbo molecular pump 122, a valve 123, a dry pump 124, a decompressor 130, and a valve 131.

### <Configurations of Partition Wall and Lifting Mechanism of Second Embodiment>

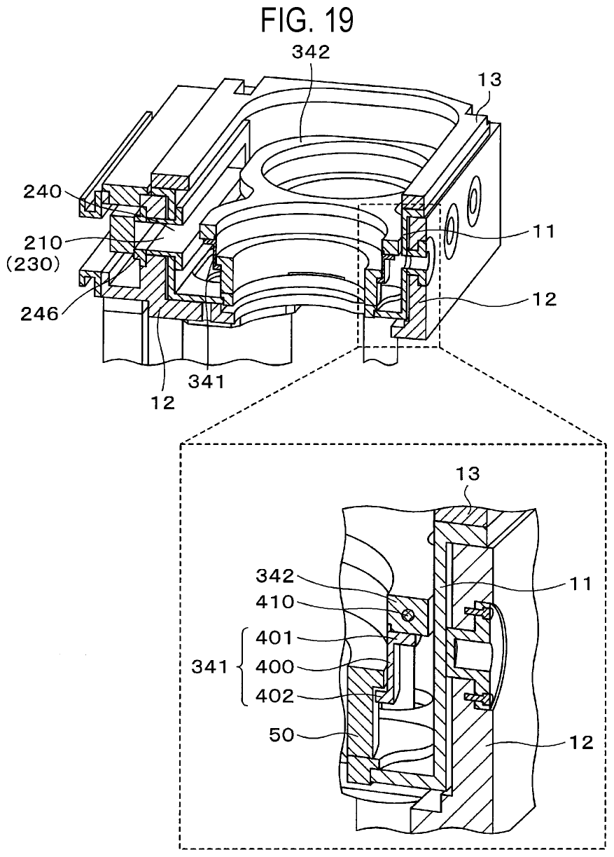

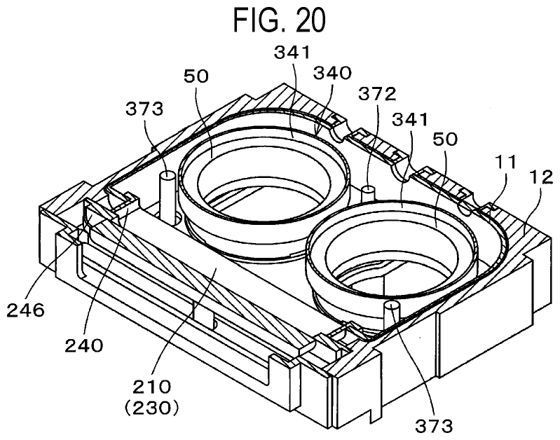

Next, configurations of the partition wall 340 and the lifting mechanism 370 described above will be described. FIG. 18 is a perspective view schematically illustrating the configurations of the partition wall 340 and the lifting mechanism 370. FIG. 19 is a vertical cross-sectional view schematically illustrating configurations of the partition wall 340 and the vicinity of the partition wall 340. FIG. 20 is a horizontal cross-sectional view schematically illustrating the configurations of the partition wall 340 and the vicinity of the partition wall 340.

As illustrated in FIGS. 18 to 20, the partition wall 340 is vertically divided to have two sub-partition walls 341 and one heater plate 342.

The two sub-partition walls 341 individually surround the two stages 20, respectively. Each sub-partition wall 341 includes a cylindrical portion 400, an upper flange portion 401, and a lower flange portion 402. The cylindrical portion 400 surrounds a stage 20. The upper flange portion 401 is provided at the upper end of the cylindrical portion 400 and extends radially outward from the cylindrical portion 400. The lower flange portion 402 is provided at the lower end of the cylindrical portion 400 and extends radially inward from the cylindrical portion 400.

The heater plate 342 is provided in common to the two sub-partition walls 341 and has a shape in which two rings are coupled in a plan view. The heater plate 342 is provided on the top surfaces of the upper flange portions 401. The heater plate 342 includes a built-in partition wall heater 410 such as a sheath heater or a cartridge heater. The partition wall heater 410 adjusts the temperature of the partition wall 340 to, for example, 120 degrees C. to 140 degrees C. As a result, for example, foreign matter contained in the processing gas can be suppressed from adhering to the partition wall 340.

With the partition wall 340 having this configuration, by raising the partition wall 340, bringing the heater plate 342 and the seal member 34 into contact with each other, and bringing the lower flange portion 402 into contact with the seal member 343, processing spaces S with high airtightness can be formed. In addition, the flow of the processing gas in the processing spaces S can be made uniform, and furthermore, the exhaust path from the processing spaces S can be controlled.

In addition, since the partition wall 340 has a vertically divided structure, for example, only the exhaust structure by the sub-partition walls 341 on the lower side can be changed without changing the specifications of the heater plate 342 on the upper side. For example, exhaust flow paths are formed inside the sub-partition walls 341, and a plurality of openings for making the processing spaces S and the exhaust flow paths communicate with each other are formed in the inner surfaces of the sub-partition walls 341. In such a case, the processing gas in the processing spaces S flow into the exhaust flow paths inside the sub-partition walls 341 through the plurality of openings and is discharged from the exhaust pipe 60.

In addition, since the partition wall 340 has a vertically divided structure, for example, it is possible to individually machine the sub-partition walls 341 and the heater plate 342 which are improved in workability and procurement performance.

The sub-partition walls 341 and heater plate 342 of the partition wall 340 are each made of metal such as aluminum or stainless steel. The surfaces of the sub-partition walls 341 and the surface of the heater plate 342, that is, the surfaces in contact with a processing gas are applied with a coating that is resistant to corrosion against the processing gas. This coating is determined depending on the type of the processing gas, and is, for example, nickel plating or the like.

Here, considering the temperature influence from the partition wall 340 to the wafers W, it is preferable that the distance between the partition wall 340 and the wafers W placed on the stages 20 is large. As illustrated in FIG. 17, a distance L between the partition wall 340 and the wafers W is larger than a conventional one, and is, for example, 10 mm or more, and more preferably 15 mm or more. In this case, since it is possible to increase the distance between the partition wall 340 and the wafers W, the temperature influence from the partition wall 340 on the wafers W is reduced. As a result, process performance can be maintained with high precision.

In the related art, a partition wall was provided with a seal member and the seal member and partition wall heater were present above the partition wall. Thus, when the inner diameter of the partition wall was increased, it was difficult to achieve a layout that allows the seal member to be compatible with the partition wall heater. In this regard, in the present embodiment, since the seal members 34 are provided on the frames 31 of the shower head 30, the partition wall heater 410 can be appropriately laid out inside the heater plate 342 even when the distance between the partition wall 340 and the wafers W is increased and the heater plate 342 becomes smaller.

The partition wall 340 may be provided with an air supplier (not illustrated) that supplies air to the partition wall 340. In such a case, the partition wall 340 can be cooled with air, and the time required for the partition wall 340 to cool down, for example, during maintenance can be shortened.

As illustrated in FIGS. 18 to 20, the lifting mechanism 370 includes an actuator 371, one drive shaft 372, and a plurality of (e.g., two) guide shafts 373. The drive shaft 372 is raised and lowered by the actuator 371, and the partition wall 340 is raised and lowered. At this time, the two guide shafts 373 prevent the partition wall 340 from tilting.

As illustrated in FIG. 16, the tip of the drive shaft 372 is connected to the heater plate 342, and the other base end is connected to the actuator 371. The actuator 371 is provided outside the outer chamber 12. The drive shaft 372 penetrates the bottom plates of the inner chamber 11 and the outer chamber 12 and extends vertically upward within the inner chamber 11. An adapter 260 is provided in portions through which the drive shaft 372 is inserted into the inner chamber 11 and the outer chamber 12, that is, the openings 214 and 234 (the portions where the drive shaft 372 is connected), as described later. In addition, in the drive shaft 372, an adapter 260 is provided with a shaft seal portion 420. A seal member 421 such as a resin O-ring is provided inside the shaft seal portion 420 to isolate the vacuum atmosphere and the air atmosphere.

The tips of the guide shafts 373 are connected to the heater plate 342, and the other base ends extend to the outside of the outer chamber 12. The guide shafts 373 penetrate the bottom plates of the inner chamber 11 and the outer chamber 12 and extend vertically upward in the inner chamber 11. In the guide shafts 373, adapters 260 are provided in portions through which the guide shafts 373 are respectively inserted into the inner chamber 11 and the outer chamber 12, that is, the openings 215 and 235 (the portions where the guide shafts 373 are connected) as described later. In addition, in the guide shafts 373, the adapters 260 are provided with shaft seal portions 422, respectively. Seal members 423 such as resin O-rings are respectively provided inside the shaft seal portions 422 to isolate the vacuum atmosphere and the air atmosphere.

In this way, since the drive shaft 372 and the guide shafts 373 are provided with the shaft seal portions 420 and 422, respectively, costs can be reduced compared to, for example, the conventional bellows seal structure. In addition, in the case of the conventional bellows seal structure, it is necessary to provide a heater around the bellows in order to suppress the adhesion of foreign matter, but when a shaft seal structure is used as in the present embodiment, such a heater is not necessary.

### <Configuration of Chamber of Second Embodiment>

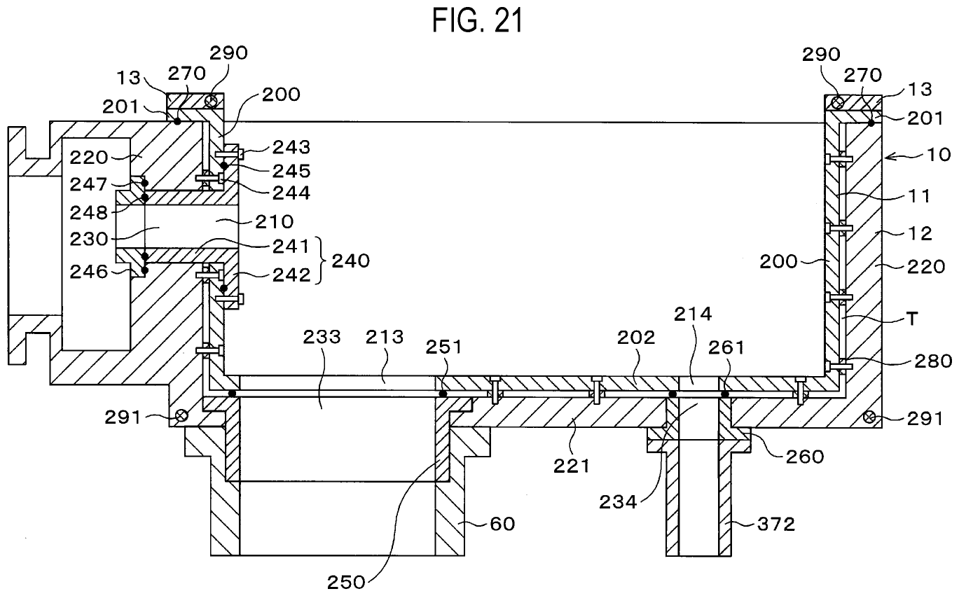

Next, configurations of the above-described chamber 10 and the vicinity of the chamber 10 will be described. FIG. 21 is a vertical cross-sectional view schematically illustrating the configurations of the chamber 10 and the vicinity of the chamber 10. The configurations of the chamber 10 and the vicinity of the chamber 10 in the wafer processing apparatus 300 are similar to those of the chamber 10 and the vicinity of the chamber 10 in the wafer processing apparatus 1 of the first embodiment. In addition, in FIG. 21, illustration of the internal configuration of the inner chamber 11 is omitted to facilitate description of the configuration of the chamber 10.

The configurations of the inner chamber 11 and the outer chamber 12 of the chamber 10 in the wafer processing apparatus 300 are similar to those of the inner chamber 11 and the outer chamber 12 in the wafer processing apparatus 1 of the first embodiment. That is, in the wafer processing apparatus 300, the configuration of the chamber 10 is as illustrated in FIGS. 5 and 6, the configuration of the inner chamber 11 is as illustrated in FIGS. 7 and 8, and the configuration of the outer chamber 12 is as illustrated in FIGS. 9 and 10. The inner chamber 11 includes a sidewall 200, a flange portion 201, a bottom plate 202, a loading/unloading port 210, a port 211, and openings 212 to 215. The outer chamber 12 includes a sidewall 220, a bottom plate 221, a loading/unloading port 230, a port 231, and openings 232 to 235.

The configuration of the hermetically closed space T in the wafer processing apparatus 300 is also similar to that of the hermetically closed space T in the wafer processing apparatus 1 of the first embodiment. That is, in the wafer processing apparatus 300, the seal structures of the hermetically closed space T are as illustrated in FIGS. 11 to 14. A seal structure of the hermetically closed space T includes an adapter 240, a main body 241, an engagement portion 242, first fastening members 243, second fastening members 244, a seal member 245, an adapter 246, a seal member 247, and a seal member 248, wherein the hermetically closed space T in the loading/unloading ports 210 and 230 is sealed. A seal structure of the hermetically closed space T includes an adapter 250 and a seal member 251, wherein the hermetically closed space T in the openings 213 and 233 is sealed. A seal structure of the hermetically closed space T includes an adapter 260 and a seal member 261, wherein the hermetically closed space T in the openings 214 and 234 (the portions where the drive shaft 372 is connected) is sealed and the hermetically closed space T in the openings 215 and 235 (the portions where the guide shafts 373 are connected) is sealed. A seal structure of the hermetically closed space T includes seal members 270, and the hermetically closed space T is sealed between the flange portions 201 and the top surfaces of the sidewalls 220. A plurality of spacers 280 are provided in the hermetically closed space T.

The configurations of heaters in the wafer processing apparatus 300 are similar to those of the heaters in the wafer processing apparatus 1 of the first embodiment. That is, as illustrated in FIG. 21, the heater ring 13 includes built-in inner heaters 290.

The outer chamber 12 is provided with outer heaters 291, such as sheath heaters or cartridge heaters, which heat the outer chamber 12. The outer heaters 291 are provided at arbitrary positions, but are provided respectively at, for example, the four corners of the bottom plate of the outer chamber 12. These inner heaters 290 and outer heaters 291 are individually controlled, and are adjustable to individual temperatures, respectively.

The outer heaters 291 adjusts the temperature of the outer chamber 12 to, for example, 80 degrees C. to 100 degrees C. Here, the inner chamber 11 is thermally independent by the hermetically closed space T, which is a vacuum insulating layer, but there is some heat transfer between the inner chamber 11 and the hermetically closed space T. In particular, since the volume of the outer chamber 12 is large and is connected to a wafer transfer device or the like outside the wafer processing apparatus 300, some heat from the inner chamber 11 escapes via the outer chamber 12. Therefore, in the present embodiment, the temperature of the inner chamber 11 is appropriately controlled by adjusting the temperature of the outer chamber 12 in advance. That is, the outer heaters 291 function as an assist for temperature adjustment of the inner chamber 11.

The temperature of the outer chamber 12, which is adjusted by the outer heaters 291, is arbitrary. However, the temperature of the inner chamber 11 is controlled to be higher than the temperature of the outer chamber 12. For example, when the chamber has a single structure as in the wafer processing apparatus disclosed in Patent Document 1, the temperature of the chamber is adjusted to, for example, 120 degrees C. to 150 degrees C. In this regard, in the wafer processing apparatus 300 of the present embodiment, since the chamber 10 has a double structure, the temperature of the outer chamber 12 can be kept lower than in the conventional case.

In addition, as described above, the temperature of the partition wall 340 is adjusted to, for example, 120 degrees C. to 140 degrees C. by the partition wall heater 410. That is, the temperature of the partition wall 340 is controlled to be higher than the temperature of the inner chamber 11. When the partition wall heater 410 is controlled by providing a temperature difference between the partition wall 340 and the inner chamber 11 in this way, the temperature of the partition wall 340 and the temperature of the inner chamber 11 can be easily controlled. The temperature of the partition wall 340 does not necessarily have to be higher than the temperature of the inner chamber 11, and may be, for example, the same as the temperature of the inner chamber 11.

### <Wafer Processing Method of Second Embodiment>

Next, wafer processing (COR processing) in the wafer processing apparatus 300 configured as described above will be described.

First, in the state in which the partition wall 340 is lowered to the retracted position, wafers W are transferred into the chamber 10 (the inner chamber 11) by a transfer mechanism (not illustrated) provided outside the wafer processing apparatus 300 and placed on respective stages 20.

Thereafter, the partition wall 340 is raised to the wafer processing position. As a result, the processing spaces S are formed by the partition wall 340.

Then, the interior of the inner chamber 11 is exhausted to a desired pressure by the exhauster 120, and a processing gas is supplied to the interior of the inner chamber 11 from the processing gas supplier 100, and COR processing is performed on the wafers W. In addition, the processing gas in the processing spaces S passes through the exhaust spaces V and the slits 53 in each inner wall 50 and is discharged from the exhauster 120.

During the COR processing, the temperature of the inner chamber 11 is adjusted to, for example, 120 degrees C. to 150 degrees C. by the inner heaters 290 (the heater ring 13), and the temperature of the outer chamber 12 is adjusted to, for example, 80 degrees C. or lower by the outer heaters 291. In addition, the hermetically closed space T is decompressed to a desired degree of vacuum by the decompressor 130 such that the hermetically closed space T functions as a vacuum insulating layer between the inner chamber 11 and the outer chamber 12. As a result, the temperature of the inner chamber 11 may be efficiently controlled by the vacuum heat insulating layer.

In addition, in order to adjust a pressure in the hermetically closed space T during the COR processing, an inert gas may be supplied to the hermetically closed space T from the inert gas supplier 110. For example, when a pressure difference occurs between the interior of the inner chamber 11 and the hermetically closed space T, an inert gas is supplied from the inert gas supplier 110 to the hermetically closed space T in order to adjust this pressure difference. Specifically, in order to suppress the processing gas from flowing into the hermetically closed space T, the pressure in the hermetically closed space T is adjusted such that the pressure inside the inner chamber 11 does not become higher than that of the hermetically closed space T. Alternatively, for example, the pressure in the hermetically closed space T is monitored with a pressure gauge (not illustrated), and the inert gas is supplied to the hermetically closed space T from the inert gas supplier 110 when the pressure becomes lower than a threshold value.

When the COR processing is terminated, the partition wall 340 is lowered to the retracted position, and the wafers W on respective stages 20 are carried out to the outside of the wafer processing apparatus 300 by the wafer transfer mechanism (not illustrated). Thereafter, the wafers W are heated by a heating device provided outside the wafer processing apparatus 300, and a reaction product produced by the COR processing is vaporized and removed. As a result, a series of COR processing is terminated.

### <Maintenance of Wafer Processing Apparatus of Second Embodiment>

Next, maintenance of the wafer processing apparatus 300 will be described. In this maintenance, for example, the inner chamber 11 is replaced. Replacing the inner chamber 11 includes changing the corrosion-resistant coating of the inner chamber 11, for example, when changing the processing gas. Alternatively, for example, after performing COR processing on a plurality of wafers W, the inner chamber 11 that has deteriorated over time may be replaced.

First, the evacuation of the hermetically closed space T by the decompressor 130 is stopped, and the inert gas is supplied into the hermetically closed space T from the inert gas supplier 110. The inert gas is supplied until the interior of the hermetically closed space T reaches atmospheric pressure.

Thereafter, the lid 14 is removed to open the interior of the inner chamber 11 to the air, the partition wall 340 is removed, and then the inner chamber 11 is replaced. Then, after forming the hermetically closed space T between the inner chamber 11 and the outer chamber 12, the hermetically closed space T is decompressed to a desired degree of vacuum by the decompressor 130. In this way, preparation for COR processing is completed.

### [Effect of Second Embodiment]

Here, the wafer processing apparatus is provided with so-called a partition wall. The partition wall is provided to surround the stages for wafers and defines processing spaces for performing etching processing on the wafers placed on the stages. With such a partition wall structure, even if an exhaust pipe for exhausting the interior of the chamber is provided at one location with respect to the chamber, the exhaust path from the processing spaces to the exhaust pipe can be controlled during the etching processing. In addition, during the etching processing, it is possible to make the flow of processing gas uniform in the processing spaces while ensuring the airtightness of the processing space.

However, in the conventional wafer processing apparatus disclosed in above-mentioned Patent Document 1, for example, the partition wall is not taken into consideration. Therefore, there is room for improvement in the conventional wafer processing apparatus, particularly in the configuration of the chamber that includes the partition wall.

In this regard, according to the above-described second embodiment, since a triple structure of the partition wall 340, the inner chamber 11, and the outer chamber 12 is provided, the flow of the processing gas in the processing spaces S can be made uniform, and the exhaust from the processing space S can also be appropriately controlled while achieving the effects of the double structure of the chamber 10 in the above-described first embodiment.

In addition, the conventional wafer processing apparatus, which has only one chamber, is configured to dissipate the heat from the partition wall to the chamber side. In this regard, according to the present embodiment, since the inner chamber 11 is provided between the partition wall 340 and the outer chamber 12, the partition wall 340 is less susceptible to external heat (heat of the outer chamber 12), so that the temperature uniformity of the partition wall 340 is improved.

In addition, according to the present embodiment, the distance between the partition wall 340 and the wafer W can be increased, and the temperature influence from the partition wall 340 on the wafers W is reduced. As a result, process performance can be maintained with high precision.

In addition, according to the present embodiment, the same effects as in the first embodiment described above can be achieved.

In addition, in the above-described embodiment, the wafer processing apparatus 300 in which two stages 20 are provided as illustrated in FIG. 16 has been described, but the above-described effects can also be achieved with the wafer processing apparatus 300 in which a single stage 20 is provided as illustrated in FIG. 15.

It is to be considered that the embodiments disclosed herein are exemplary in all respects and not restrictive. Various types of omissions, substitutions, and changes may be made to the above-described embodiments without departing from the scope and spirit of the appended claims.

In addition, for example, in the above-described embodiments, the case where COR processing is performed on the wafer W has been described as an example, but the technique of the present disclosure is also applicable to other wafer processing apparatuses that use a processing gas, such as a plasma processing apparatus.

### EXPLANATION OF REFERENCE NUMERALS

1: wafer processing apparatus, 11: inner chamber, 12: outer chamber, 100: processing gas supplier, W: wafer

1. A substrate processing apparatus for processing a substrate, comprising:
an inner chamber in which the substrate is accommodated;
an outer chamber provided outside the inner chamber; and
a processing gas supplier configured to supply a processing gas to an interior of the inner chamber,
wherein the inner chamber is configured to be detachable from the outer chamber, and
wherein the outer chamber is provided such that the outer chamber does not come into contact with the processing gas supplied to the interior of the inner chamber.

2. The substrate processing apparatus of claim 1, further comprising:
a stage on which the substrate is placed;
a partition wall provided inside the inner chamber to surround the stage;
a lifting mechanism configured to raise and lower the partition wall; and
a seal member provided on a bottom surface of a shower head of the processing gas supplier,
wherein a top surface of the partition wall and the seal member are in contact with each other in a state in which the partition wall is raised.

3. The substrate processing apparatus of claim 2, wherein the lifting mechanism includes:
a drive shaft configured to raise and lower the partition wall; and
a shaft seal provided on the drive shaft.

4. The substrate processing apparatus of claim 3, wherein a hermetically closed space is defined between the inner chamber and the outer chamber, and
wherein the substrate processing apparatus further comprises:
a decompressor configured to evacuate the space; and
an inert gas supplier configured to supply an inert gas to the space.

5. The substrate processing apparatus of claim 4, further comprising:
a controller configured to control the decompressor to evacuate the space so that the space functions as a vacuum heat insulating layer.

6. The substrate processing apparatus of claim 5, wherein the controller is configured to control the inert gas supplier to supply the inert gas to the space to adjust an internal pressure of the space.

7. The substrate processing apparatus of claim 4, wherein a spacer is provided to come into contact with the inner chamber and the outer chamber.

8. The substrate processing apparatus of claim 4, further comprising:
an exhauster configured to exhaust the interior of the inner chamber,
wherein the decompressor and the exhauster are controlled individually.

9. The substrate processing apparatus of claim 1, wherein the inner chamber includes a flange portion which protrudes outward from an upper end of the inner chamber and is provided above the outer chamber, and
wherein a gap is formed between a bottom surface of the flange portion and a top surface of the outer chamber.

10. The substrate processing apparatus of claim 1, further comprising:
an adapter configured to connect the inner chamber and an outside of the inner chamber.

11. The substrate processing apparatus of claim 10, further comprising:
an exhauster configured to exhaust the interior of the inner chamber,
wherein the adapter is provided to connect the inner chamber and the exhauster.

12. The substrate processing apparatus of claim 10, wherein a loading/unloading port for the substrate is provided in a sidewall of the inner chamber and a sidewall of the outer chamber, and
wherein the adapter is provided to connect the inner chamber and the outer chamber at the loading/unloading port.

13. The substrate processing apparatus of claim 1, further comprising:
an inner heater configured to heat the inner chamber.

14. The substrate processing apparatus of claim 13, further comprising:
an outer heater configured to heat the outer chamber,
wherein the inner heater and the outer heater are controlled individually.

15. The substrate processing apparatus of claim 2, further comprising:
a partition wall heater configured to heat the partition wall.

16. The substrate processing apparatus of claim 13, wherein the inner chamber includes a flange portion which protrudes outward from an upper end of the inner chamber, and
the inner heater is provided on a top surface side of the flange portion.

17. The substrate processing apparatus of claim 14, wherein a temperature of the inner heater is higher than a temperature of the outer heater.

18. The substrate processing apparatus of claim 15, further comprising:
an inner heater configured to heat the inner chamber,
wherein a temperature of the partition wall heater is higher than a temperature of the inner heater.

19. The substrate processing apparatus of claim 1, wherein the inner chamber has a gas contact surface to which a corrosion-resistant coating against the processing gas is performed.

20. The substrate processing apparatus of claim 1, wherein a hermetically closed space is defined between the inner chamber and the outer chamber, and
wherein the substrate processing apparatus further comprises:
a decompressor configured to evacuate the space; and
an inert gas supplier configured to supply an inert gas to the space.
